(19) United States
(12) Patent Application Publication
(10) Pub. No.: US 2024/0229911 A9
(43) Pub. Date: Jul. 11, 2024

(54) Method for automatic detection of wear, gear damage and/or bearing damage on a gearbox

(71) Applicant: IMS GEAR SE & CO. KGAA, Donaueschingen (DE)

(72) Inventors: Florian WERSCHLER, Rottweil (DE); Dario KATAVA, Donaueschingen (DE); Daniel REHLE, Niedereschach (DE); Johannes STOEHER, Villingen-Schwenningen (DE)

(21) Appl. No.: 18/381,455

(22) Filed: Oct. 18, 2023

(30) Foreign Application Priority Data
Oct. 19, 2022 (EP) 22202382.2

(51) Int. Cl. F16H 57/01; G01M 13/021; G01M 13/04

(52) U.S. Cl. CPC F16H 57/01; G01M 13/021; G01M 13/04; F16H 2057/012

(57) ABSTRACT

A method for detecting wear and/or damage to a motor-gearbox unit with a motor and a gearbox coupled to the motor on the output side includes a detection module determining an input and/or output torque either directly or indirectly as a measured variable that can be unambiguously correlated with the input and/or output torque when the gearbox is moved by the motor. A signal curve is respectively generated for such movements, which signal curve reflects the input and/or output torque respectively determined directly or indirectly as a function of a variable correlated with the position of the gearbox. At least some of these signal curves are analyzed automatically, wherein a region of the variable correlated with the position of the gearbox is identified, to which a feature characteristic of gearbox damage can be assigned for the respective signal curve.

Due to the advancing autonomization in the vehicle and manufacturing industries, automatic condition monitoring of individual components and assemblies is increasingly coming to the fore.

An additional digital fallback level is becoming increasingly important, in particular in the case of safety-relevant components and assemblies. A method for timely detection prior to function-endangering damage is consequently of utmost importance.

Such a method is known, for example, from DE 10 2016 222 660 A1, in which the following method steps are carried out to detect damage and/or wear to translationally moving parts of an electromechanical drive:
measuring the electric current supplied to the electric drive,
performing a time-frequency analysis,
comparing the frequency spectrum of the measured electric current determined from the time-frequency analysis with a predetermined frequency spectrum, and
triggering of an error signal when a deviation of predetermined magnitude is detected from the comparison of the two frequency spectra.

Furthermore, U.S. Pat. No. 4,965,513 A describes a method for monitoring the operating conditions of an electrically driven valve by performing an analysis of the motor current. For this purpose, various methods of frequency analysis are applied to the motor current in order to generate a noise signature of the motor current, by means of which noise signature wear and abnormal operating states are to be detected. It should be possible to determine different characteristic operating states of the electrically driven valve by means of the noise signature, in particular the sum of all mechanical load changes could be detectable, which load changes are manifested in the frequency spectrum and in the amplitudes. If such noise signatures are generated in different time periods during operation, it should be possible to determine aging and wear or abnormal operating conditions.

These methods known from the prior art suffer from the fact that the processing of the motor current signals is insufficient to make reliable statements regarding wear and damage under varying environmental influences and/or operating conditions of the motor gearbox unit with an electric motor and a gearbox connected to the output side thereof. The approach described in EP 4 012 426 A1 addresses these problems, but there is still room for improvement with regard to the use of resources and the early detection of damage.

The tasks of the invention therefore consist in providing a method for automatic detection of gear damage to a gearbox, which enables improved, resource-saving and early damage detection, which at the same time is largely independent of varying environmental influences and/or operating conditions of the motor-gearbox unit.

In the method according to the invention for detecting wear and/or damage to a motor-gearbox unit with a motor and a gearbox coupled to the motor on the output side, a detection module determines an input and/or output torque either directly—for example, with a torque measuring shaft—or indirectly—for example, by measuring the motor current(s)—as a measured variable that can be unambiguously correlated with the input and/or output torque when the gearbox is moved by the motor. In this way, a signal curve correlating to the torque is respectively generated for such movements, which signal curve reflects the input and/or output torque respectively determined directly or indirectly as a function of a variable correlated with the position of the gearbox.

The term “position of the gearbox” is understood to mean the changing orientation and/or spatial position of the components of the gearbox during the movement of the gearbox. A position of a gearbox can therefore be described, for example, by which teeth of the gearwheels forming the gearbox are currently engaged with each other or, by way of example, which torsion angle a gearwheel has relative to a reference point.

For the sake of simplicity, the term “gearbox damage” is used below as a collective term for wear and damage to gears or gear damage and bearing damage.

Furthermore, for reasons of clarity, the previously described signal curve correlating with the torque, which reflects the directly or indirectly determined input and/or output torque as a function of a variable correlated with the position of the gearbox, is referred to in the following in simplified form as “signal curve” or “signal curves.”

According to the method of the invention, at least some of these signal curves are moreover analyzed automatically. In this automated analysis, a region of the variable correlated with the position of the gearbox is respectively identified in which a defined characteristic feature of gearbox damage occurs.

In the event that there is gearbox damage, the same regularly influences the torque behavior of the motor, which, for example, increases the input torque through appropriate control due to a temporarily inefficient torque transmission in order to ensure the required output torque.

Thus, in the simplest case, such an analysis may simply consist of determining a maximum value in a signal curve, determining a region under a portion of a signal curve, or determining a location on the signal curve where it is most likely to exhibit a predetermined curve shape. In more complex cases, a pre-selection or pre-processing of signal curves can also be performed in advance of the application of the respective criterion.

In each signal curve that is analyzed, a region (which may correspond, for example, to an angular position of a particular gear of the gearbox) that fulfills the criterion used for damage detection (for example, maximum in the signal curve) is identified.

This identified region is automatically assigned to a histogram class (which is to say, in other words, entered into this class so that the number of events or alternatively regions assigned to this class increases, which can be done in particular by an immediate summation; but also, for example, by keeping a respective list of the signal curves assigned to a class), and it is automatically checked whether there is an unexpected accumulation of entries in a class in the histogram (in particular, by comparing the number of events added up or by determination and comparison of list lengths). If this is the case, there is indeed gearbox damage. In this case, a warning message can, for example, be generated so that the damage can be repaired before a total failure of the motor-gearbox unit occurs.

A first key finding underlying the invention is that the application of a criterion for damage detection is possible on signal curves of motor-gearbox units without gearbox damage, which as a rule, then leads to substantially randomly distributed results for the position at which said criterion locates the gearbox damage in the respective signal curve. Even if, in an exceptional case in a special application, no random distribution of said alleged gearbox damage occurs, the expected distribution of results can be easily determined for an undamaged gearbox and can be used as the basis for damage monitoring, for example, by performing a weighted background correction.

When, however, gearbox damage begins to occur, the change in the signal curve caused by the damage and amplified as the damage becomes more severe will cause the expected distribution of results to change significantly in the region or regions of the signal curve where, for example, a damaged tooth is loaded for torque transmission.

A second key finding is that, as a rule, it is not necessary to determine the exact position or alternatively the type of gearbox damage, but rather only to detect that gearbox damage is present at some position, since the resulting need for a gearbox change is independent of which component of the gearbox is damaged.

This allows for an approach based upon histograms, in which the path/angle traversed during the recording of the signal curve is divided into regions and for each of said regions a count is made as to how often the damage detection criterion was met in said region. For this purpose, a memory with a size of a few kilobytes is sufficient, in which only very simple arithmetic operations need to be executed. The evaluation of whether real gearbox damage is present, which is manifested by the deviation of the distribution in this histogram from an expected distribution, in particular a random distribution, is also mathematically attributable to simple comparison operations. The computing power required by the use of the method according to the invention is therefore just as low as the memory space required.

In a preferred embodiment of the method, an automated pre-selection of the signal curves to be analyzed is performed.

It can, in particular, be provided that only signal curves containing torque information on gearbox positions that completely cover a specified region are allowed for further evaluation during the preselection.

Alternatively or additionally, the preselection can be carried out in such a way that, during the preselection, only signal curves, in which the deviation of the absolute maximum and of the absolute minimum from the mean value of the signal curve does not exceed a predefined limit value, are taken into account. The logic of this measure becomes apparent when considering extreme changes in load. Short-term torque peaks, especially upon a reversal of direction of rotation and/or a load reversal, make it difficult to determine reliable damage-indicating characteristics.

In a preferred variant of the method, a constant component is determined and removed from signal curves to be analyzed, which enables the signal curve to be analyzed. This determination can, for example, be carried out by forming a moving average of the signal curve to smooth the signal curve; the constant component can then be removed by subtracting this moving average from the corresponding associated measured value of the signal curve.

If a division by the smoothed signal curve is additionally performed, a correction of torque-dependent, periodically-occurring amplitudes can be enabled. Additional smoothing and/or low-pass filtering can also eliminate any interference signals from the signal curve.

An alternative approach provides for the determination and removal of the constant component by applying a bandpass filter to the signal curve. An advantage of this method is that a comparatively limited computing power is required to perform it, which facilitates its execution while respecting standards in the automotive field.

Preferably, in so doing, the upper and lower frequency limits of the bandpass filter are chosen as a function of input speed in such a manner that the gear engagement frequency of the gearbox components to be monitored represents the main component of the periodic fluctuations of the signal.

A normalization of the signal curve with the determined constant component can further improve the reliability of the analysis.

Preferably, the histogram is stored in the form of a number array which, for each region of the variable correlated with the position of the gearbox, stores the number nᵢ of signal curves, during the analysis of which the characteristic feature of gearbox damage was assigned to this region, as well as the number of rollovers rᵢ of this angular range. In this case, i indexes the respective angular range. This represents an efficient storage method that requires a small permanent memory space.

Inasmuch as the numbers in the array can become very large with an increasing number of measuring cycles and thereby in turn require more memory space, and inasmuch as there are angular ranges that are rarely rolled over, a correction or a type of normalization of the damage events to the number of rollovers is preferred.

The following rule is used to determine the corrected values n_{i-new} and r_{i-new} within the number array:

1. n_{i-new}=nᵢ−n̅·rᵢ/rₛᵤₚ

2. r_{i-new}=rᵢ−c Equation (1)

n̅ hereby represents the mean value of all entries nᵢ. The maximum number of rollovers in the entire array is denoted by rₛᵤₚ. Any negative n_{i-new} values that arise are set to a constant, positive value. Moreover, possible decimal places are removed. Additionally, to limit the decimal places of rᵢ after a cell by cell application of equation (1) 1, a constant value c (by way of example, the smallest rᵢ in the number array) is subtracted from rᵢ in step 2 of equation (1). This method ensures, on the one hand, the limitation of the decimal places of the whole number array as well as an adequate correlation of the number of rollovers rᵢ with their corresponding damage events nᵢ.

To decide whether or not a gearbox damage warning is issued, the number array can be evaluated by means of a limit value comparison. In this case, a limit value comparison according to the formula

$$Equation ( 2 )$$

$$X = \frac{{n}_{max}}{\frac{1}{j - 1} [ {\sum }_{i} {n}_{i} - {n}_{max} ]} \to \{ \begin{matrix}Gearbox iO , & i f X < {T}_{rel} \\ Gearbox niO , & if X \geq {T}_{rel}\end{matrix}$$

has proven successful. In this formula, X represents the maximum number nₘₐₓ normalized to the mean value of all entries nᵢ without nₘₐₓ and Tᵣₑₗ represents the threshold value beyond which a gearbox damage warning is issued. i represents the index of the angular range and is the run variable over which summation is performed, j represents the number of classes into which the entire angular range is divided.

In a preferred embodiment of the invention, during the automated check as to whether there is an unexpected accumulation of entries in a class in the histogram, such that there is wear and/or gearbox damage, it is provided that a non-randomly distributed background is corrected. In this way, systematic effects that may appear depending on the specific use of the motor-gearbox unit can be corrected. The method presented enables the detection of gearbox damage to different gearbox types. Mentioned here by way of example are spur gearboxes, helical gearboxes and worm gearboxes, which among others are also used for safety-relevant applications in the automotive field.

Depending on the application, there may be situations in which certain gearbox damage is only noticeable in one running direction of the motor-gearbox arrangement. If signal curves are analyzed separately according to running direction, reliable detection of such gearbox damage is also possible.

The invention is explained in greater detail below with reference to the figures. Wherein:

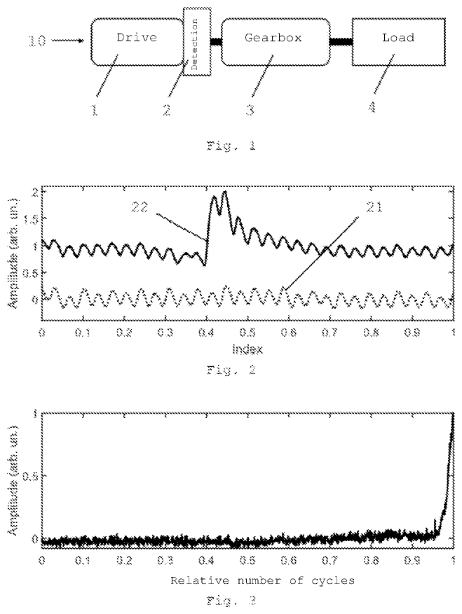

FIG. 1: shows an exemplary mechanical construction that can be monitored for the occurrence of gear damage by means of the method according to the invention,

FIG. 2: shows a comparison of an exemplary signal curve of an intact gearbox and a damaged gearbox,

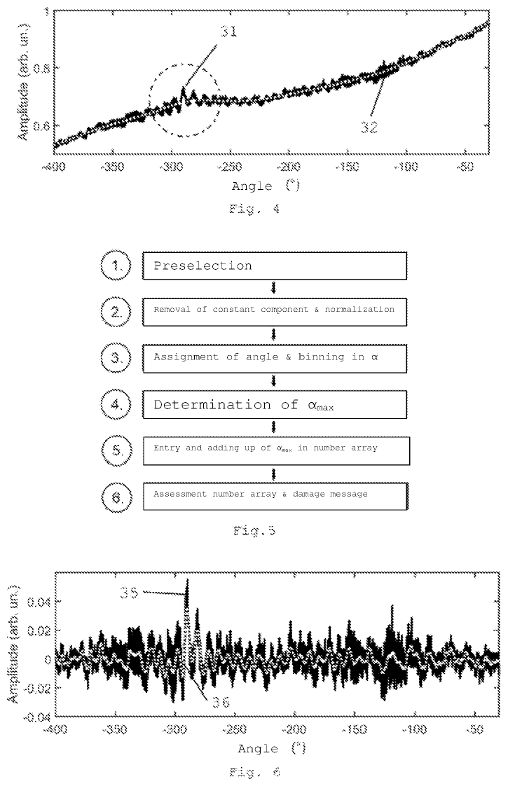

FIG. 3: shows a representation of the development of the maximum of the measured signal curves of a gearbox as a function of the load cycle,

FIG. 4: shows a real signal curve of a damaged gearbox of a motor-gearbox unit,

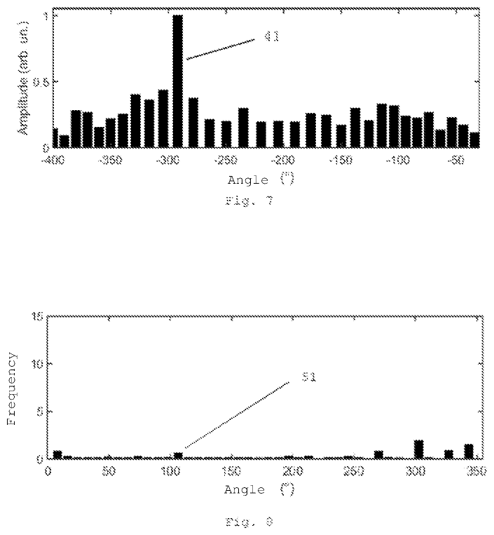

FIG. 5: shows a flow chart of one possible analysis of signal curves,

FIG. 6: shows the intermediate result obtained from the real signal curve of FIG. 4 after the execution of the second step of the flow chart of FIG. 5,

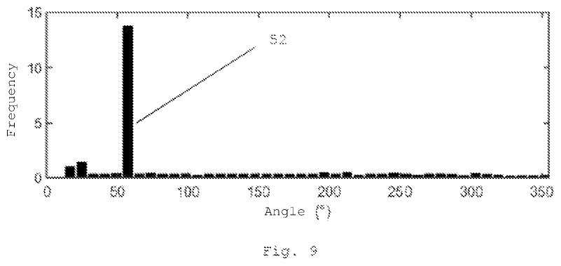

FIG. 7: shows the intermediate result obtained from the intermediate result of FIG. 6 after the execution of the third step of the flow chart of FIG. 5,

FIG. 8: shows the histogram obtained after running through the flow chart of FIG. 5 for signal curves that fulfill the damage criterion at randomly distributed angular positions (which represents the behavior of an intact gearbox), and

FIG. 9: shows the histogram for a damaged gearbox obtained after running through the flow chart of FIG. 5.

FIG. 1 shows an exemplary mechanical construction of an motor-gearbox unit 10, which can be monitored for the occurrence of gearbox damage by means of the method according to the invention.

The motor-gearbox unit 10 necessarily comprises a motor 1, which is, in particular, here implemented by means of an electric motor. The specific construction type of the electric motor is not important; by way of example, it can be a servo motor, a brushless direct current motor or even a brushed electric motor.

It is essential that the motor-gearbox unit 10 comprises a detection module 2, which is configured and operable to enable the direct or indirect recording of the input and/or output torque as a measured variable that can respectively be unambiguously correlated with the torque, in particular one that is proportional thereto, such as, for example, the time-resolved motor current. This measured variable is therefore repeatedly measured during operation of the motor-gearbox unit 10, whereas the gearbox or the components that form it are in different positions, in particular engagement positions, such that during a movement of the motor-gearbox unit 10, a signal curve is respectively generated, which reflects the input and/or output torque respectively determined either directly or indirectly as a function of a variable correlated with the position of the gearbox.

The gearbox 3 to be monitored, which, by way of example, is here a helical-/worm gearbox, is driven by the drive 1, so that a movement, which is to say, for example, a plunger being moved, is brought about by the drive under the influence of a load 4, the magnitude of which can change.

According to the invention, the signal curves recorded by this detection module 2 are used as a parameter for the occurrence of gear damage, which signal curves enable the direct or indirect detection of the torque curve of a gearbox under load and enable the identification of irregularities in the signal curve, which allow early damage detection.

FIG. 2 illustrates the usability of signal curves recorded with such a detection module 2 for the identification of gearbox damage. A torque curve 21 of an intact gearbox 3 is shown as a dashed line and the torque curve 22 of a damaged gearbox 3, in which a tooth root has a crack, is shown as a solid line.

In this example, the data shown represent input torques acquired by means of a torque measuring shaft as a function of a variable correlated with the angle of rotation, whereas the respective gearbox 3 is moved at a defined speed from a defined start position to a defined end position. In this example, the respective measured values are plotted against a relative sampling index, which is therefore a variable that is proportional to the measuring time and can therefore be reproducibly assigned to a given gearbox position, in order to generate the respective signal curve.

The gearbox position can generally be determined by a variety of variables correlated with it, for example, as a function of a running time of the motor, by monitoring the position of the rotor of the motor, by monitoring the position of a plunger moved by the motor-gearbox unit 10 or by similar measures.

The signal curve 22 of the damaged gearbox 3 differs from the signal curve 21 of the intact gearbox 3 by the maximums that occur. These significantly pronounced modulations in the signal curve 22 are caused by the engagement of a damaged tooth, which modulations result in the drive motor increasing the input torque to provide the required output torque due to inefficient torque transmission.

Such anomalies can be used to define criteria for detecting damage. Examples of such criteria are extreme values of the data (maximums, minimums, etc.), the area (sum, integral) under the maximums/minimums of a certain region correlating with the angle of rotation, or similar characteristics. If damage occurs, one or a plurality of these characteristics increases significantly and marks the beginning of damage that is occurring.

To illustrate this fact, FIG. 3 shows a representation of an exemplary feature that can be derived from the comparison according to FIG. 2, specifically in the form of the maximum of the individual signal curves, as a function of the respective load cycle. A load cycle is thereby, respectively, the movement of the gearbox 3 from the defined start position to the defined end position. For each of these load cycles, a torque curve has been measured by the detection module 2. Each of the data points entered in FIG. 3 corresponds to the maximum amplitude of the torque curve of the associated load cycle.

It can be seen in FIG. 3 that after about 95 percent of the maximum number of load cycles, the value of this characteristic, which is to say, the maximum amplitude in the respective signal curve correlated with the torque, begins to rise, which, in this example, is an indicator of the onset of an occurring tooth breakage.

Under ideal conditions, such as those that can be achieved, for example, in endurance tests with motor-gearbox units 10 in the laboratory, gearbox damage can thus be reliably determined from directly or indirectly obtained torque measurement data. These conditions are ideal in two respects:

Firstly, the environmental conditions are controllable and as a consequence virtually constant, which facilitates the precise identification of the features. In the case of an in situ measurement of an operation of a motor-gearbox unit 10 in a real application, the situation is much more complex. The signal curves of two successive travel cycles can hereby differ drastically one from the other, for example, in terms of speed and output load over time.

Secondly, computing power and memory space are regularly available on a large scale for automated data analysis under laboratory conditions, whereas these resources are available to a lesser extent when operating under real conditions (for example, in a vehicle).

To illustrate this fact, FIG. 4 shows an example of a torque curve 31, determined with a torque measuring shaft, of a motor gearbox unit 10, with a damaged gearbox 3, which is subjected to changing loads during operation, as a solid line. Here, the torque is plotted against an angular position at the output of the motor-gearbox unit, which can, for example, be determined directly with a rotary encoder, or indirectly from the temporal signal curve. The region in which the effects of the damaged tooth can be seen is highlighted with a circle; a moving average 32 of the measurement signal is shown as a dashed line. This example immediately shows how complex the task of detecting such damage in a signal curve and reliably assigning it to an angular position is, even when it is certain that damage is present.

The challenge here is that a comparability between measurement signals, recorded under different measurement conditions, must be achieved with as little computational effort as possible.

If one applies the steps of the analysis procedure shown in FIG. 5, then even in this case, a reliable monitoring for gearbox damage is, however, possible using manageable hardware resources.

Initially, a preselection of the measuring cycles to be used is made (point (1.) in FIG. 5). In this case, only cycles with defined angular ranges are allowed for the evaluation. Furthermore, the deviation of the absolute maximum and of the absolute minimum from the mean value of the signal curve should not exceed a limit value. The first measure ensures that all desired angular ranges are included in the signal curve and, if necessary, undesired regions of the signal curve are ignored; the second measure ensures that the fluctuations caused by the output torque do not become so large that they cannot be corrected.

In point (2.) in FIG. 5, the constant component is removed. This can, in particular, occur making use of two approaches:
I) The difference between the strongly smoothed signal curve (dashed line in FIG. 4) and the original signal curve (solid line in FIG. 4) is formed. Furthermore, a division by the strongly smoothed signal curve can optionally be performed to correct torque-dependent, periodically-occurring amplitudes and/or optionally a further smoothing and/or low-pass filtering can be performed to eliminate possible interference signals from the signal curve.
II) A bandpass filter is applied to the signal. The upper and lower frequency limits in this case can be selected as a function of input speed in such a manner that the gear engagement frequency of the gearbox under consideration represents the major component of the periodic fluctuations of the signal curve. An advantage of this method is the simpler implementation in common programming languages.

It is true for both approaches that they can be carried out with minimal computational effort and simple mathematical operations.

FIG. 6 shows the corrected signal 35 obtained after application of method I) as a solid line and for better clarity the moving average 36 over this corrected signal is shown as a dashed line. In particular, after averaging, the trained eye can now detect maximums in the corrected signal curve above approximately −300° that indicate gearbox damage.

In the next two steps, (3.) and (4.), in FIG. 5, the region of the variable correlated with the position of the gearbox is now identified, to which a defined feature characteristic of gearbox damage can be assigned for the respective signal curve. In this example, the occurrence of the maximum in the signal curve represents the characteristic feature for gearbox damage. In step (4.), in FIG. 5, the position αₘₐₓ at which the characteristic gearbox damage feature occurs is determined.

In this case, the angle scale of FIG. 6 is converted for this purpose into an angle scale that indicates the corresponding position of the monitored gearbox component (which always lies between 0° and 360°). Moreover, the corrected signal curve is divided into classes, each class comprising a fixed angular range, in this example, each class is 10° of the angular scale. All values of the corrected signal curve within a class are summed up. The resulting signal 41 is shown schematically in the form of a bar graph in FIG. 7. The angle αₘₐₓ at the position of the bar with the highest value in the bar graph (41) is identified; it corresponds to the respective region that is identified with the variable correlated with the position of the gearbox, in which the defined feature characteristic of gearbox damage is found for the respective signal curve. This leads to a considerable reduction in the amount of data to be further processed, since the high-resolution corrected signal curve is converted into a structure with few relevant data points, which are the respective bins with the respectively associated sum.

If, due to the detection module 2, the detected signal curve is available as a function of the angle scale, which indicates the corresponding position of the monitored gearbox component, the corrected signal curve generated according to steps (1.) and (2.) in FIG. 5 can be directly classified into classes and summed up within a class.

A αₘₐₓ is determined for each individual signal curve passing the preselection (step (1.) in FIG. 5). This value is entered into a histogram (51,52), in which the frequency with which αₘₐₓ occurs is mapped (point (5.) in FIG. 5).

FIG. 8 shows a histogram (51), which is based on randomly generated signal curves intended to represent an intact gearbox. These signal curves were evaluated with the previously described algorithm according to FIG. 5. As expected, it can be seen that the extracted αₘₐₓ are virtually randomly distributed, so that the histogram (51) forms a uniformly distributed base level. It may also occur in some applications that this uniformly distributed base level only emerges when one corrects for a systematic effect that overlays this distribution.

If a further thirty signal curves are added to the approximately thirty evaluated data sets, in which, in this example, a damaged worm wheel is present, the histogram 52 shown in FIG. 9 results, which now has a prominent maximum at the point at which the damaged tooth is loaded, in this case, at approximately 70°.

In order to satisfy the requirements of a small available permanent memory space, the method according to the invention requires only a number array with a size of a few kilobytes, which must be stored permanently. Table 1 schematically shows how such an array is constructed with a class variable of 10° and the class index i, and in which manner the individual cells can be “filled.”

TABLE 1

| Angle α (°) | 0 | 10 | 20 | 30 | 40 | . . . | 360 |
|---|---|---|---|---|---|---|---|
| Number nᵢ | 2 | 4 | 9 | 3 | 25 | . . . | 0 |
| Rollovers rᵢ | 30 | 28 | 25 | 25 | 5 | . . . | 2 |

Here, only the number nᵢ of individual events at certain angular positions and the number of rollovers rᵢ of this angular range are counted up and stored.

For example, a simple query of the angular position of the maximum in the number array, combined with a limit value comparison, can enable an evaluation of the state of the gearbox. Since the numbers in the array can become very large with an increasing number of measuring cycles and thus require more memory space, and since there are angular ranges that are rarely rolled over, a correction or alternatively a kind of normalization of the damage events to the number of rollovers must be made.

The following rule is used to determine the corrected values n_{i-new} and r_{i-new} within the number array:

1. n_{i-new}=nᵢ−n̅·rᵢ/rₛᵤₚ

2. r_{i-new}=rᵢ−c Equation (1)

n̅ hereby represents the mean value of all entries nᵢ. The maximum number of rollovers in the entire array is denoted by rₛᵤₚ. Possible negative n_{i-new} values are set to a constant, positive value. Moreover, possible decimal places are removed. Additionally, to limit the decimal places of rᵢ after a cell by cell application of equation (1) 1, a constant value c (by way of example, the smallest rᵢ in the number array) is subtracted from rᵢ in step 2. of equation (1). This method ensures, on the one hand, the limitation of the decimal places of the entire number array as well as an adequate correlation of the number of rollovers rᵢ with their corresponding damage events nᵢ.

After each application of the rule from equation (1) to all cells, a limit value comparison enables an evaluation of the state of the gearbox. Equation (2) symbolically represents the limit value comparison:

$$Equation ( 2 )$$

$$X = \frac{{n}_{max}}{\frac{1}{j - 1} [ {\sum }_{i} {n}_{i} - {n}_{max} ]} \to \{ \begin{matrix}Gearbox iO , & i f X < {T}_{rel} \\ Gearbox niO , & if X \geq {T}_{rel}\end{matrix}$$

X is hereby the maximum number nₘₐₓ divided by the mean value of the individual entries nᵢ without nₘₐₓ. j hereby represents the number of array classes. If X exceeds a previously defined relative limit value Tᵣₑₗ, then the gearbox is declared as “out of order.” As a consequence, a maintenance recommendation can be issued (FIG. 4, step (6.)).

The specified logic represents a possibility for a condition monitoring of a motor-gearbox unit 10, which saves computing resources and allows system monitoring to be achieved with the lowest possible additional costs without additional hardware.

### LIST OF REFERENCE SIGNS

1 Motor
2 Detection module
3 Gearbox
4 Load
Motor-gearbox unit
21 Signal curve
22 Signal curve
31 Signal curve
32 Moving average
Corrected signal curve
36 Moving average
41 Histogram
51 Histogram
52 Histogram

1. Method for detecting wear, gear damage and/or bearing damage to a motor-gearbox unit (10) with a motor (1) and a gearbox (3) coupled to the motor on the output side, in which
a detection module (2) determines an input and/or output torque either directly or indirectly as a measured variable that can be unambiguously correlated with the input and/or output torque when the gearbox (3) is moved by the motor (1), such that a signal curve (21, 22, 31) is respectively generated for such movements, which signal curve reflects the input and/or output torque respectively determined directly or indirectly as a function of a variable correlated with the position of the gearbox (3),
at least some of these signal curves (21, 22, 31) are analyzed automatically, wherein a region of the variable correlated with the position of the gearbox (3) is identified, to which a defined feature characteristic of gearbox damage can be assigned for the respective signal curve (21, 22, 31),
the identified region is automatically assigned to a class of a histogram (51,52), and
it is automatically checked whether there is an unexpected accumulation of entries in a class in the histogram (51,52), such that wear and/or gearbox damage is present.

2. Method according to claim 1,
characterized in that an automated preselection of the signal curves (21,22,31) to be analyzed is performed.

3. Method according to claim 2,
characterized in that during the preselection only signal curves (21,22,31) that contain torque information on gearbox positions that sweep over specified regions are allowed for further evaluation.

4. Method according to claim 2,
characterized in that during the preselection only signal curves (21,22,31) in which the deviation of the overall maximum and the overall minimum from the mean value of the signal curve does not exceed a specified limit value are allowed for further evaluation.

5. Method according to claim 1,
characterized in that a constant component is determined and removed from signal curves (21,22,31) to be analyzed.

6. Method according to claim 5,
characterized in that the constant component is determined by forming a moving average (32) of the signal curve (21, 22) for smoothing the signal curve, and in that the constant component is removed by subtracting this moving average (32) from the corresponding associated measured value of the unsmoothed signal curve (21, 22, 31).

7. Method according to claim 6,
characterized in that, moreover, a division by the smoothed signal curve is carried out in order to undertake a correction of torque-dependent, periodically-occurring amplitudes and/or,
optionally, a further smoothing and/or low-pass filtering is/are carried out in order to eliminate possible interference signals from the signal curve.

8. Method according to claim 6,
characterized in that the constant component is determined and removed by applying a bandpass filter to the signal curve (21,22,31).

9. Method according to claim 8,
characterized in that the upper and lower frequency limits of the bandpass filter are chosen as a function of input speed in such a manner that the gear engagement frequency of the gearbox (3) components to be monitored represents the main component of the periodic fluctuations of the signal.

10. Method according to claim 5,
characterized in that a normalization of the signal curve (21,22,31) with the determined constant component takes place.

11. Method according to claim 1,
characterized in that the histogram (50, 51) is stored as a number array which, for each region of the variable correlated with the position of the gearbox (3), stores the number nᵢ of signal curves (21, 22, 31), during the analysis of which the characteristic feature of gearbox damage was assigned to this region, as well as the number of rollovers rᵢ of this angular range.

12. Method according to claim 11,
characterized in that the number array is updated at least once with corrected values n_{i-new} and r_{i-new}, which are determined according to the rule
1. n_{i-new}=nᵢ−n̅·rᵢ/rₛᵤₚ
2. r_{i-new}=rᵢ−c,
wherein
n̅ represents the mean value of all entries nᵢ,
rₛᵤₚ denotes the maximum number of rollovers in the entire array, possible negative n_{i-new} values are set to a constant positive value,
possible decimal places are removed,
and c is a constant value, in particular the smallest rᵢ in the number array before the update.

13. Method according to claim 11,
characterized in that the number array is evaluated by means of a limit value comparison.

14. Method according to claim 13,
characterized in that the limit value comparison according to the formula
$$X = \frac{{n}_{max}}{\frac{1}{j - 1} [ {\sum }_{i} {n}_{i} - {n}_{max} ]} \to \{ \begin{matrix}Gearbox iO , & i f X < {T}_{rel} \\ Gearbox niO , & if X \geq {T}_{rel}\end{matrix}$$
is executed, wherein
X is the calculated present value,
Tᵣₑₗ represents the threshold value above which a gearbox damage warning is issued,
nₘₐₓ describes the maximum number of damage events in the number array,
rₘₐₓ indicates the corresponding number of rollovers,
nᵢ represents the i-th entry of the damage events in the number array,
rᵢ is the respective corresponding number of rollovers and j is the total number of angular ranges.

15. Method according to claim 1,
characterized in that during the automated check as to whether there is an unexpected accumulation of entries in a class in the histogram (51,52), such that there is wear and/or gearbox damage, a non-randomly distributed background is corrected.

16. Method according to claim 1,
characterized in that the signal curves (21,22,31) are analyzed separately according to running direction.
